(19) United States
(12) Patent Application Publication
(10) Pub. No.: US 2003/0117773 A1
(43) Pub. Date: Jun. 26, 2003

(54) Thermal module

(76) Inventors: Nien-Tien Cheng, Tu-Chen (TW); Chien-Tu Cheng, Tu-Chen (TW); Yi-Chang Liu, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/136,231

(22) Filed: Apr. 30, 2002

(30) Foreign Application Priority Data
Dec. 26, 2001 (TW) 90223013

(51) Int. Cl. H05K 7/20

(52) U.S. Cl. 361/700; 174/15.2; 165/104.33

(57) ABSTRACT

A thermal module (1) includes a base (30), a fin group (40), a heat pipe (50) and a connective interface. The fin group comprises a plurality of closely-spaced parallel fins (42). A first end of the heat pipe is attached to the base, and an opposite second end of the heat pipe is received in a slot defined in the fin group. The connective interface is disposed between the second end of the heat pipe and the fin group. The connective interface has high thermal conductivity, and readily connects with the heat pipe and the fin group.

### BACKGROUND OF THE INVENTION

1. Field of the Invention

The present invention relates to thermal modules, and particularly to a thermal module having a base, a heat pipe and a fin group.

2. Prior Art

An electrical system such as a computer system often has components that generate excessive heat. This can adversely affect operation of the computer system, and cause the system to become unstable. Therefore, a thermal module is widely used to remove heat from a heat-generating component of a computer. Developments in computer chip technology have given computers central processing units (CPUs) with more functions and faster processing speeds. Accordingly, modern CPUs generate copious amounts of heat. At the same time, modern computers and their components are continually being miniaturized. Thus, compact thermal modules having very high heat dissipation efficiency are becoming increasingly important.

As shown in FIG. 1, a conventional thermal module includes a base (not shown) for conducting heat from a heat-generating electronic device, a fin group 10 for dissipation of heat, and two heat pipes 20 connected between the base and the fin group 10. The fin group 10 includes a plurality of fins 12, and defines two through slots 14 extending through the fins 12. Ends of the heat pipes 20 are interferentially fixed in the slots 14 of the fin group 10.

Unfortunately, heat conducted from the heat pipes 20 to the fin group 10 encounters high thermal resistance at interfaces therebetween. Furthermore, the heat pipes 20 are liable to become dislodged from the fin group 10 after prolonged use, due to repeated thermal expansion and shrinkage.

### SUMMARY OF THE INVENTION

Accordingly, an object of the present invention is to provide a thermal module having high heat conductivity between a fin group and a heat pipe thereof.

Another object of the present invention is to provide a thermal module having means for securely fixing a heat pipe to a fin group thereof.

To achieve the above-mentioned objects, a thermal module of the present invention comprises a base, a fin group, a heat pipe and a connective interface. The fin group comprises a plurality of closely-spaced parallel fins. A first end of the heat pipe is attached to the base, and an opposite second end of the heat pipe is received in a slot defined in the fin group. The connective interface is disposed between the second end of the heat pipe and the fin group. The connective interface has high thermal conductivity, and readily connects with the heat pipe and the fin group.

Other objects, advantages and novel features of the present invention will be drawn from the following detailed description of a preferred embodiment of the present invention with attached drawings, in which:

### BRIEF DESCRIPTION OF THE DRAWINGS

FIG. 1 is a perspective view of a conventional thermal module;

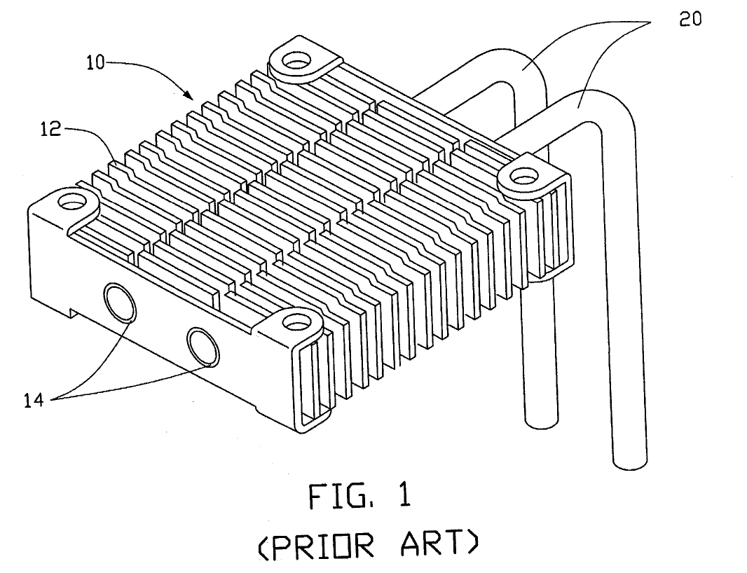

FIG. 2 is an exploded perspective view of a thermal module in accordance with the present invention; and

FIG. 3 is an assembled view of FIG. 2.

### DETAILED DESCRIPTION OF THE PREFERRED EMBODIMENT

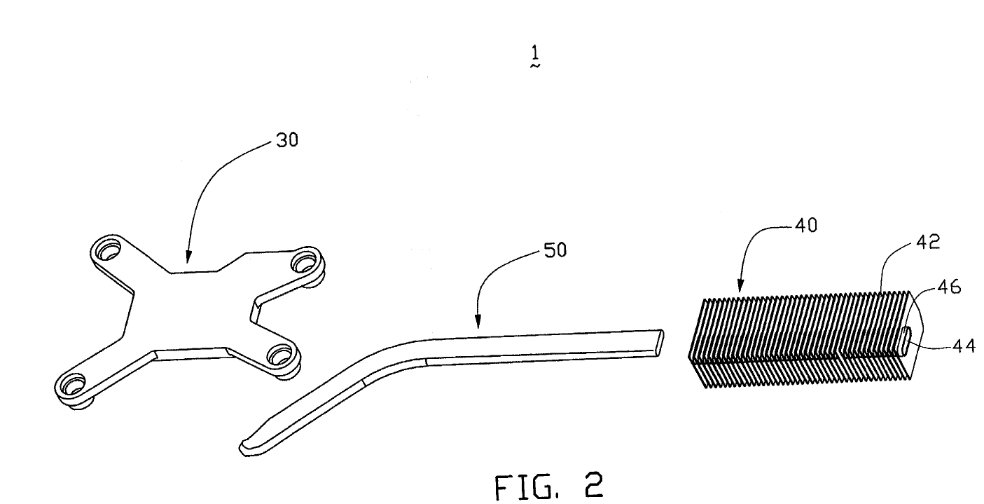

Referring to FIG. 2, a thermal module 1 in accordance with the present invention includes a base 30, a fin group 40, a heat pipe 50 and a connective interface (not shown). The fin group 40 includes a plurality of closely-spaced parallel fins 42. Each fin 42 defines a hole 44 therein. A generally oval-shaped side wall 46 extends perpendicularly from the fin 42 around the hole 44. Thus the holes 44 of the fins 42 in the fin group 40 cooperatively define a slot through the fin group 40. Similarly, the side walls 46 of the fins 42 in the fin group 40 cooperatively form a slot wall of the fin group 40.

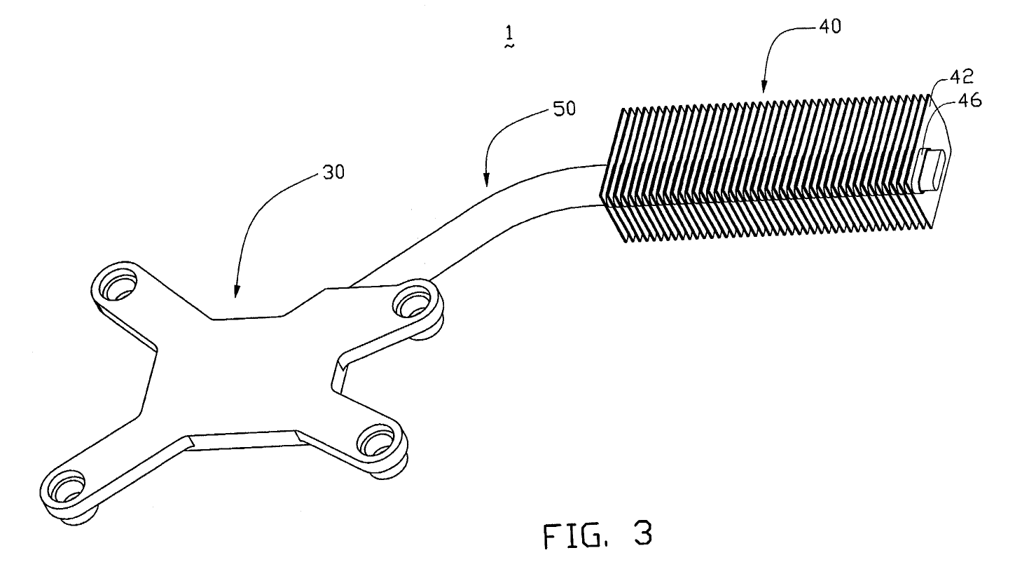

Referring to FIG. 3, in assembly, a first end of the heat pipe 50 is attached to a bottom face of the base 30. An opposite second end of the heat pipe 50 is received in the slot of the fin group 40. The connective interface (not shown) is disposed between the slot wall of the fin group 40 and the second end of the heat pipe 50. In the preferred embodiment, the connective interface is tin paste. Alternatively, the connective interface may be tin foil or another suitable material. The connective interface has high thermal conductivity, and therefore minimizes thermal resistance between the heat pipe 50 and the fin group 40. Furthermore, the connective interface readily connects with the heat pipe 50 and the fin group 40, thereby ensuring secure connection between the heat pipe 50 and the fin group 40.

It is understood that the invention may be embodied in other forms without departing from the spirit thereof. Thus, the present examples and embodiment are to be considered in all respects as illustrative and not restrictive, and the invention is not to be limited to the details given herein.

1. A thermal module comprising:
a base;
a heat pipe having a first end attached to the base and an opposite second end;
a fin group defining a slot receiving the second end of the heat pipe therein; and
a connective interface disposed between the second end of the heat pipe and the fin group.

2. The thermal module as claimed in claim 1, wherein the connective interface comprises tin paste.

3. The thermal module as claimed in claim 1, wherein the connective interface comprises tin foil.

4. The thermal module as claimed in claim 1, wherein the fin group comprises a plurality of closely-spaced parallel fins, each of the fins defines a hole therein, and the holes cooperatively define the slot of the fin group.

5. The thermal module as claimed in claim 4, wherein a side wall extends perpendicularly from each of the fins around the hole, and the side walls of the fins cooperatively form a slot wall of the fin group.

6. The thermal module as claimed in claim 5, wherein the connective interface is disposed between the second end of the heat pipe and the slot wall of the fin group.

7. A method of removal of heat from a heat generating device, comprising the steps of:
providing a base attached to the heat generating device;
attaching one end of a heat pipe to said base;
providing a fin group with therein a slot receiving an opposite end of said heat
pipe with a non-interference fit; and
disposing connective interface in said slot and between said fin group and said heat pipe to not only fasten the fin group and the heat pipe together but also increase thermal conductivity therebetween.

8. A thermal module comprising:
a base;
a heat pipe attached to said base; and
a fin group attached to said heat pipe away from said base; wherein
said fin group defines a slot to receive said heat pipe in a non-interference fit and a connective interface is disposed in the slot between said fin group and said heat pipe to not only grasp said fin group and said heat pipe together but also increase thermal conductivity therebetween.
